(19) United States
(12) Patent Application Publication
(10) Pub. No.: US 2022/0213129 A1
(43) Pub. Date: Jul. 7, 2022

(54) SILICON OXIDE FILM, MATERIAL FOR GAS BARRIER FILM, AND METHOD FOR PRODUCING SILICON OXIDE FILM

(71) Applicants: TOSOH CORPORATION, Shunan-shi, Yamaguchi (JP); SAGAMI CHEMICAL RESEARCH INSTITUTE, Ayase-shi, Kanagawa (JP)

(72) Inventors: Shun SUGIMOTO, Ayase-shi, Kanagawa (JP); Hirokazu CHIBA, Ayase-shi, Kanagawa (JP); Ryoji TANAKA, Ayase-shi, Kanagawa (JP); Marina FUKAWA, Ayase-shi, Kanagawa (JP)

(21) Appl. No.: 17/602,201

(22) PCT Filed: Apr. 3, 2020
(86) PCT No.: PCT/JP2020/015354

§ 371 Date: Oct. 7, 2021

(30) Foreign Application Priority Data
Apr. 9, 2019 (JP) 2019-073978
Jul. 19, 2019 (JP) 2019-133403
Feb. 20, 2020 (JP) 2020-026878

(51) Int. Cl. C07F 7/18; C23C 16/44; C23C 16/40; C23C 16/505; C23C 16/18

(52) U.S. Cl. CPC C07F 7/18; C23C 16/4414; C23C 16/18; C23C 16/505; C23C 16/402

(57) ABSTRACT

To provide a silicon oxide film which exhibits high gas barrier performance even under a thin film condition.

A silicon oxide film characterized by satisfying the following requirements (1) and (2):

(1) the water vapor transmission rate (WVTR) at a film thickness of at most 500 nm is at most 9.0×10⁻³ g/m²·day,
(2) the carbon concentration in the film, as measured by X-ray photoelectron spectroscopy (XPS), is at most 3.0 atom %.

### TECHNICAL FIELD

The present invention relates to a silicon oxide film useful as a gas barrier film, a material for a gas barrier film, and a method for producing a silicon oxide film using the material for a gas barrier film.

### BACKGROUND ART

As a gas barrier film having gas barrier performance imparted by being formed on a plastic substrate or plastic film, there is a gas barrier film formed by a physical deposition method, CVD (chemical vapor deposition) method, etc. As the material for such a gas barrier film, an oxide such as SiO₂ or Al₂O₃, or a nitride such as SiN, may be mentioned.

For example, Patent Document 1 proposes a film for a gas barrier bag having a gas barrier layer of SiO₂ formed by a plasma enhanced chemical vapor deposition (PECVD) method using, as a raw material, a mixed gas of hexamethyldisiloxane, 1,1,3,3-tetramethyldisiloxane, 1,3-divinyl-1,1,3,3-tetramethyldisiloxane, etc., oxygen and an inert gas such as helium or argon. However, this film has a high water vapor transmission rate (WVTR) of from 0.2 to 0.6 g/m²·day and a high oxygen transmission rate of from 0.4 to 0.5 cc/m²·day, which are indices for gas barrier performance, i.e. the gas barrier performance is low.

In Patent Document 2, a polyethylene naphthalate (PEN) film is produced wherein a SiO₂ gas barrier layer is formed under a film deposition pressure of at most 20 Pa by a PECVD method using tetraethoxysilane and oxygen as raw materials. However, the film deposition pressure was high, and the WVTR was as large as 1.7×10⁻³ g/m²·day, so the gas barrier performance was still not sufficient.

Further, Patent Document 3 discloses a method for forming a low permittivity insulating film by a PECVD method using an organic silane compound. Although the WVTR is not described, the power of the radio frequency power supply (RF power supply) at the time of film deposition is as low as 75 W, and it is a method to form a low-density thin film, and therefore, it is inferred that the film formed is not suitable for use as a gas barrier material.

Patent Document 4 discloses a film with a very low WVTR of from 1.0×10⁻⁵ to 2.9×10⁻⁵ g/m²·day by using a laminated film of organic and inorganic thin films. However, the organic and inorganic thin films need to be film-deposited by separate film deposition processes, which increases the number of production processes, whereby the production cost of the gas barrier film is increased.

Patent Document 5 discloses a gas barrier film with a WVTR as low as 2.1×10⁻⁴ g/m²·day in a single layer of 800 nm in thickness, formed by film deposition of an organosilane compound having a specific structure by a PECVD method.

### PRIOR ART DOCUMENTS

### Patent Documents

Patent Document 1: Japanese Patent No. 4139446

Patent Document 2: JP-A-2016-176091

Patent Document 3: Japanese Patent No. 4863182

Patent Document 4: Japanese Patent No. 5394867

Patent document 5: Japanese Patent No. 6007662

### DISCLOSURE OF INVENTION

### Technical Problem

In recent years, along with thinning of gas barrier films, higher gas barrier performance has been required even for thinner films. In general, the WVTR tends to increase as the film thickness becomes thinner. An object of the present invention is to provide a silicon oxide film having high gas barrier performance which shows a WVTR of at most 10⁻³ g/m²·day order even at a film thickness of at most 500 nm, a material for a gas barrier film, and a method of producing a silicon oxide film using the material for a gas barrier film.

### Solution to Problem

The present inventors have studied hard to solve the above problem and, as a result, have found that the above problem can be solved by using a silicon oxide film and a material for a gas barrier film having specific characteristics, and thus have arrived at accomplishing the present invention.

That is, the present invention has the following embodiments.

[1] A silicon oxide film characterized by satisfying the following requirements (1) and (2):
(1) the water vapor transmission rate (WVTR) at a film thickness of at most 500 nm is at most 9.0×10⁻³ g/m²·day,
(2) the carbon concentration in the film, as measured by X-ray photoelectron spectroscopy (XPS), is at most 3.0 atom %.
[2] The silicon oxide film according to [1], wherein the water vapor transmission rate (WVTR) at a film thickness of at most 500 nm is from 1.0×10⁻⁶ to 9.0×10⁻³ g/m²·day.
[3] A material for a gas barrier film for a chemical vapor deposition method, consisting of an organosilane compound represented by the following formula (1):

Rₙ¹—Si—(OR²)₄₋ₙ (1)

(R¹ represents a C₁₋₂₀ alkyl group or a hydrogen atom, n represents an integer from 1 to 3, when n is at least 2, the plurality of R¹ may be the same or different from one another, or two R¹ may be bonded to each other to form an alkanediyl group, R² represents a C₁₋₁₀ alkyl group, when n is at most 2, the plurality of R² may be the same or different from one another.)
[4] The material for a gas barrier film according to [3], where R¹ is a hydrogen atom or a C₁₋₅ alkyl group.
[5] The material for a gas barrier film according to [3] or [4], wherein R² is a C₁₋₃ alkyl group.
[6] The material for a gas barrier film according to any one of [3] to [5], wherein R¹ is selected from the group consisting of a hydrogen atom, a methyl group, an ethyl group, a propyl group, an isopropyl group, a butyl group, an isobutyl group, a sec-butyl group, a tert-butyl group, a pentyl group, a cyclopentyl group, a 1-methylbutyl group, a 2-methylbutyl group, a 3-methylbutyl group, a 1-ethylpropyl group, a 1,1-dimethylpropyl group, a 1,2-dimethylpropyl group and a 2,2-dimethylpropyl group.
[7] The material for a gas barrier film according to any one of [3] to [6], wherein the material for a gas barrier film is any one of dimethoxymethylsilane, trimethoxymethylsilane, ethyldimethoxysilane, ethyltrimethoxysilane, dimethoxypropylsilane, trimethoxypropylsilane, dimethoxyisopropylsilane, trimethoxyisopropylsilane, butyldimethoxysilane, butyltrimethoxysilane, isobutyldimethoxysilane, isobutyltrimethoxysilane, sec-butyldimethoxysilane, sec-butyltrimethoxysilane, tert-butyldimethoxysilane, tert-butyltrimethoxysilane, dimethoxypentylsilane, trimethoxypentylsilane, 1-methylbutyldimethoxysilane, 1-methylbutyltrimethoxysilane, 2-methylbutyldimethoxysilane, 2-methylbutyltrimethoxysilane, 3-methylbutyldimethoxysilane, 3-methylbutyltrimethoxysilane, 1,1-dimethylpropyldimethoxysilane, 1,1-dimethylpropyltrimethoxysilane, 1,2-dimethylpropyldimethoxysilane, 1,2-dimethylpropyltrimethoxysilane, 2,2-dimethylpropyldimethoxysilane, 2,2-dimethylpropyltrimethoxysilane, cyclopentyldimethoxysilane, cyclopentyltrimethoxysilane, diethoxymethylsilane, triethoxymethylsilane, diethoxyethylsilane, triethoxyethylsilane, diethoxypropylsilane, triethoxypropylsilane, diethoxyisopropylsilane, triethoxyisopropylsilane, butyldiethoxysilane, butyltriethoxysilane, isobutyldiethoxysilane, isobutyltriethoxysilane, sec-butyldiethoxysilane, sec-butyltriethoxysilane, tert-butyldiethoxysilane, tert-butyltriethoxysilane, diethoxypentylsilane, triethoxypentylsilane, diethoxy-1-methylbutylsilane, triethoxy-1-methylbutylsilane, diethoxy-2-methylbutylsilane, triethoxy-2-methylbutylsilane, diethoxy-3-methylbutylsilane, triethoxy-3-methylbutylsilane, diethoxy-1,1-dimethylpropylsilane, triethoxy-1,1-dimethylpropylsilane, diethoxy-1,2-dimethylpropylsilane, triethoxy-1,2-dimethylpropylsilane, diethoxy-2,2-dimethylpropylsilane, triethoxy-2,2-dimethylpropylsilane, cyclopentyldiethoxysilane, cyclopentyltriethoxysilane, dimethoxydimethylsilane, diethoxydimethylsilane, diethyldimethoxysilane, diethoxydiethylsilane and methoxytrimethylsilane.

[8] A method for producing a silicon oxide film as defined in [1] or [2], wherein the material for a gas barrier film as defined in any one of [3] to [7] is formed into a film by a plasma enhanced chemical vapor deposition method under such a condition that the deposition pressure is at least 0.01 Pa and less than 20 Pa.

[9] The method for producing a silicon oxide film according to [8], wherein the film is formed by the plasma enhanced chemical vapor deposition method under such a condition that the power of the radio frequency power supply (RF power supply) is at least 100 W.
[10] The method for producing a silicon oxide film according to [8] or [9], wherein the film is formed by the plasma enhanced chemical vapor deposition method under such a condition that the power density of the radio frequency power supply (RF power supply) is at least 0.1 W/cm².
[11] A laminated film comprising a silicon oxide film as defined in [1] or [2] and a substrate.
[12] A gas barrier film made of a silicon oxide film as defined in [1] or [2].
[13] A gas barrier film made of a laminated film as defined in [11].

### Advantageous Effects of Invention

The silicon oxide film of the invention is suitable for a gas barrier film, an insulating film, a gate oxide film of semiconductor, a protective film, etc. Among them, it is particularly suitable for a gas barrier film because it has a low water vapor transmission rate (WVTR) of at most 9.0×10⁻³ g/m²·day even when the film thickness is at most 500 nm.

### DESCRIPTION OF EMBODIMENTS

In the following, the present invention will be described in detail.

<Silicon Oxide Film>

The silicon oxide film of the present invention has a water vapor transmission rate (WVTR) at a thickness of at most 500 nm, preferably from 50 to 500 nm, more preferably from 100 to 500 nm, particularly preferably from 200 to 500 nm, of at most 9.0×10⁻³ g/m²·day, preferably from 1.0×10⁻⁶ to 9.0×10⁻³ g/m²·day, more preferably from 1.0×10⁻⁶ to 9.0×10⁻⁴ g/m²·day, particularly preferably from 1.0×10⁻⁴ to 9.0×10⁻⁴ g/m²·day.

Here, the water vapor transmission rate (WVTR) is one measured by a gas chromatography method (GC method).

Further, the silicon oxide film of the present invention has a carbon concentration in the film of at most 3.0 atom %, preferably at most 1.5 atom %, particularly preferably at most 1.0 atom %, as measured by X-ray photoelectron spectroscopy (XPS).

Further, the thickness of the silicon oxide film is preferably at least 10 nm, more preferably from 50 nm to 1,000 nm, particularly preferably from 100 nm to 1,000 nm, to realize high gas barrier performance.

Here, the gas barrier film of the present invention means the impermeable performance to gases such as oxygen, nitrogen, carbon dioxide and water vapor. Further, the gas barrier performance is evaluated by the water vapor transmission rate (WVTR) for the reason that it is generally adopted as a measurement index in the material field concerned.

The silicon oxide film of the present invention may be made to be a laminated film comprising a silicon oxide film and a substrate.

The substrate may, for example, be polyethylene terephthalate (PET), polyethylene naphthalate (PEN), polycarbonate (PC), polyamide (PA), polyimide (PI), cycloolefin polymer (COP), polyethylene (PE), polypropylene (PP), polystyrene (PS), polyvinyl chloride (PVC), polyvinyl alcohol (PVA), triacetyl cellulose (TAC), polyethersulfone (PES), cycloolefin copolymers (COC), polyacrylonitrile (PAN), ethylene-vinyl alcohol copolymer (EVOH), ABS resin, methacrylate resin, epoxy resin, modified polyphenylene ether, polyacetal, polybutylene terephthalate, polyacrylate, polyarylate, polysulfone, polyamideimide, polyether imide, polyphenylene sulfide, polyether ether ketone, fluororesin, etc. Among them, polyethylene terephthalate (PET), polyethylene naphthalate (PEN), polycarbonate (PC), polyamide (PA), polyimide (PI), cycloolefin polymer (COP), polystyrene (PS), polyvinyl chloride (PVC), polyvinyl alcohol (PVA), triacetyl cellulose (TAC), polyethersulfone (PES), methacrylate resin, epoxy resin, etc., are preferred. Particularly preferred are polyethylene terephthalate (PET), polyethylene naphthalate (PEN), polycarbonate (PC), polyamide (PA), polyimide (PI), cycloolefin polymers (COP), etc.

The laminated film has a visible light transmittance of preferably at least 80%, more preferably at least 85%, particularly preferably at least 88%.

Here, the visible light transmittance is a value of the average transmittance (including the substrate) at the wavelength of from 380 to 780 nm as measured by using a spectrophotometer (manufactured by Hitachi High-Technologies, U-4100). Further, the average transmittance of the substrate is also a value measured by the same device.

The laminated film has a surface roughness (Ra) of preferably at most 10 nm, more preferably at most 5.0 nm, particularly preferably at most 3.0 nm. Here, the surface roughness (Ra) is measured by an atomic force microscopy.

The thickness of the laminated film (the total thickness of the silicon oxide film and the substrate) is preferably at least 10 μm, more preferably from 50 μm to 2,000 μm, particularly preferably from 100 μm to 1,000 μm. The preferred thickness of the silicon oxide film in the laminated film is as described above.

<Material for Gas Barrier Film>

The material for the gas barrier film is a material for a silicon oxide film for the chemical vapor deposition method, consisting of an organosilane compound (also referred to as organosilane compound (1)) represented by the following formula (1).

Rₙ¹—Si—(OR²)₄₋ₙ (1)

In the formula (1), R¹ represents a C₁₋₂₀ alkyl group or a hydrogen atom. n represents an integer of from 1 to 3. When n is at least 2, the plurality of R¹ may be the same or different from one another, and two R¹ may be bonded to each other to form an alkanediyl group. R² represents a C₁₋₁₀ alkyl group. When n is at most 2, the plurality of R² may be the same or different from one another.

The C₁₋₂₀ alkyl group of R¹ in the formula (1) may have any structure of being linear, branched or cyclic. Further, in the case of having a plurality of R¹ in molecule, one having two R¹ bonded to each other to form an alkanediyl group, is also included in the scope of the present invention. As the C₁₋₂₀ alkyl group, from such a viewpoint that high gas barrier performance is obtainable and the vapor pressure is high which is suitable for vaporization, a C₁₋₁₀ alkyl group is preferred, a C₁₋₅ alkyl group is more preferred, and a C₁₋₄ alkyl group is particularly preferred. The plurality of R¹ may be the same or different from one another.

As R¹ in the C₁₋₂₀ alkyl group, a methyl group, an ethyl group, a propyl group, an isopropyl group, a butyl group, an isobutyl group, a sec-butyl group, a tert-butyl group, a pentyl group, a 1-methylbutyl group, a 2-methylbutyl group, a 3-methylbutyl group, a 1-ethylpropyl group, a 1,1-dimethylpropyl group, a 1,2-dimethylpropyl group, a 2,2-dimethylpropyl group, a cyclopentyl group, a hexyl group, a cyclohexyl group, an octyl group, a nonyl group, a decyl group, an icosyl group, etc., may be exemplified.

Two R¹ may be bonded to each other to form an alkanediyl group, and as such an alkanediyl group, e.g. a propane-1,3-diylgroup, a butane-1,4-diylgroup, a pentane-1,4-diylgroup, a pentane-1,5-diylgroup, a hexane-2,5-diyl group, a hexane-1,6-diylgroup, a heptane-1,7-diylgroup, etc., may be exemplified.

From such a viewpoint that raw materials are readily available, and the vapor pressure of the material for the gas barrier film represented by the formula (1) is high, R¹ is preferably a methyl group, an ethyl group, a propyl group, an isopropyl group, a butyl group, an isobutyl group, a sec-butyl group, a tert-butyl group, a pentyl group, a 1-methylbutyl group, a 2-methylbutyl group, a 3-methylbutyl group, a 1-ethylpropyl group, a 1,1-dimethylpropyl group, a 1,2-dimethylpropyl group, a 2,2-dimethylpropyl group, a hexyl group, an octyl group or a nonyl group, and more preferably a methyl group, an ethyl group, a propyl group, an isopropyl group, a butyl group, an isobutyl group, a sec-butyl group, a tert-butyl group, a pentyl group, a 1-methylbutyl group, a 2-methylbutyl group, a 3-methylbutyl group, an 1-ethylpropyl group, a 1,1-dimethylpropyl group, a 1,2-dimethylpropyl group or a 2,2-dimethylpropyl group.

As the C₁₋₁₀ alkyl group in R², a methyl group, an ethyl group, a propyl group, an isopropyl group, a cyclopropyl group, a butyl group, an isobutyl group, a sec-butyl group, a tert-butyl group, a pentyl group, a 1-methylbutyl group, a 2-methylbutyl group, a 3-methylbutyl group, a 1-ethylpropyl group, a 1,1-dimethylpropyl group, a 1,2-dimethylpropyl group, a 2,2-dimethylpropyl group, etc., may be mentioned. Among them, from such a viewpoint that the raw material is readily available, a methyl group, an ethyl group, a propyl group or an isopropyl group is preferred, and a methyl group or an ethyl group is more preferred.

n is an integer of from 1 to 3.

As specific examples of the organosilane compound represented by the formula (1), the following ones may be mentioned.

Dimethoxymethylsilane, trimethoxymethylsilane, ethyldimethoxysilane, ethyltrimethoxysilane, dimethoxypropylsilane, trimethoxypropylsilane, dimethoxyisopropylsilane, trimethoxyisopropylsilane, butyldimethoxysilane, butyltrimethoxysilane, isobutyldimethoxysilane, isobutyltrimethoxysilane, sec-butyldimethoxysilane, sec-butyltrimethoxysilane, tert-butyldimethoxysilane, tert-butyltrimethoxysilane, dimethoxypentylsilane, trimethoxypentylsilane, 1-methylbutyldimethoxysilane, 1-methylbutyltrimethoxysilane, 2-methylbutyldimethoxysilane, 2-methylbutyltrimethoxysilane, 3-methylbutyldimethoxysilane, 3-methylbutyltrimethoxysilane, 1-ethylpropyldimethoxysilane, 1-ethylpropyltrimethoxysilane, 1,1-dimethylpropyldimethoxysilane, 1,1-dimethylpropyltrimethoxysilane, 1,2-dimethylpropyldimethoxysilane, 1,2-dimethylpropyltrimethoxysilane, 2,2-dimethylpropyldimethoxysilane, 2,2-dimethylpropyltrimethoxysilane, cyclopentyldimethoxysilane, cyclopentyltrimethoxysilane, cyclohexyldimethoxysilane, cyclohexyltrimethoxysilane,

diethoxysilane, trimethoxysilane, diethoxymethylsilane, triethoxymethylsilane, diethoxyethylsilane, triethoxyethylsilane, diethoxypropylsilane, triethoxypropylsilane, diethoxyisopropylsilane, triethoxyisopropylsilane, butyldiethoxysilane, butyltriethoxysilane, isobutyldiethoxysilane, isobutyltriethoxysilane, sec-butyldiethoxysilane, sec-butyltriethoxysilane, tert-butyldiethoxysilane, tert-butyltriethoxysilane, diethoxypentylsilane, triethoxypentylsilane, 1-methylbutyldiethoxysilane, 1-methylbutyltriethoxysilane, 2-methylbutyldiethoxysilane, 2-methylbutyltriethoxysilane, 3-methylbutyldiethoxysilane, 3-methylbutyltriethoxysilane, 1-ethylpropyldiethoxysilane, 1-ethylpropyltriethoxysilane, 1,1-dimethylpropyldiethoxysilane, 1,1-dimethylpropyltriethoxysilane, 1,2-dimethylpropyldiethoxysilane, 1,2-dimethylpropyltriethoxysilane, 2,2-dimethylpropyldiethoxysilane, 2,2-dimethylpropyltriethoxysilane, cyclopentyldiethoxysilane, cyclopentyltriethoxysilane, cyclohexyldiethoxysilane, cyclohexyltriethoxysilane,

tripropoxysilane, methyltripropoxysilane, ethyltripropoxysilane, tripropoxypropylsilane, tripropoxyisopropylsilane, butyltripropoxysilane, isobutyltripropoxysilane, sec-butyltripropoxysilane, tert-butyltripropoxysilane, pentyltriisopropoxysilane, 1-methylbutyltriisopropoxysilane, 2-methylbutyltriisopropoxysilane, 3-methylbutyltriisopropoxysilane, 1-ethylpropyltriisopropoxysilane, 1,1-dimethylpropyltriisopropoxysilane, 1,2-dimethylpropyltriisopropoxysilane, 2,2-dimethylpropyltriisopropoxysilane, cyclopentyltriisopropoxysilane,

methoxydimethylsilane, dimethoxydimethylsilane, ethoxydimethylsilane, diethoxydimethylsilane, dimethylpropoxysilane, dimethyldipropoxysilane, dimethylisopropoxysilane, dimethyldiisopropoxysilane, diethylmethoxysilane, diethyldimethoxysilane, ethoxydiethylsilane, diethoxydiethylsilane, diethylpropoxysilane, diethyldipropoxysilane, diethylisopropoxysilane, diethyldiisopropoxysilane, diisopropylmethoxysilane, diisopropyldimethoxysilane, diisopropylethoxysilane, diisopropyldiethoxysilane, diisopropylpropoxysilane, diisopropyldipropoxysilane, diisopropylisopropoxysilane, diisopropyldiisopropoxysilane, di-sec-butylmethoxysilane, di-sec-butyldimethoxysilane, di-sec-butylethoxysilane, di-sec-butyldiethoxysilane, di-sec-butylpropoxysilane, di-sec-butyldipropoxysilane, di-sec-butylisopropoxysilane, di-sec-butyldiisopropoxysilane, di-tert-butylmethoxysilane, di-tert-butyldimethoxysilane, di-tert-butylethoxysilane, di-tert-butyldiethoxysilane, di-tert-butylpropoxysilane, di-tert-butyldipropoxysilane, di-tert-butylisopropoxysilane, di-tert-butyldiisopropoxysilane, methoxytrimethylsilane, ethoxytrimethylsilane, triethylmethoxysilane, ethoxytriethylsilane, 1,1-dimethoxy-1-silacyclopentane, 1,1-diethoxy-1-silacyclopentane, 1,1-dimethoxy-1-silacyclopentane, etc.

As the organosilane compound represented by the formula (1), among the above, the following ones are preferred, since they provide materials for gas barrier films with high vapor pressure or low WVTR.

Dimethoxymethylsilane, trimethoxymethylsilane, ethyldimethoxysilane, ethyltrimethoxysilane, dimethoxypropylsilane, trimethoxypropylsilane, dimethoxyisopropylsilane, trimethoxyisopropylsilane, butyldimethoxysilane, butyltrimethoxysilane, isobutyldimethoxysilane, isobutyltrimethoxysilane, sec-butyldimethoxysilane, sec-butyltrimethoxysilane, tert-butyldimethoxysilane, t-butyltrimethoxysilane, 1-methylbutyldimethoxysilane, 1-methylbutyltrimethoxysilane, 2-methylbutyldimethoxysilane, 2-methylbutyltrimethoxysilane, 3-methylbutyldimethoxysilane, 3-methylbutyltrimethoxysilane, 1,1-dimethylpropyldimethoxysilane, 1,1-dimethylpropyltrimethoxysilane, 1,2-dimethylpropyldimethoxysilane, 1,2-dimethylpropyltrimethoxysilane, 2,2-dimethylpropyldimethoxysilane, 2,2-dimethylpropyltrimethoxysilane, trimethoxycyclopentylsilane, diethoxymethylsilane, triethoxymethylsilane, ethyldiethoxysilane, ethyltriethoxysilane, diethoxypropylsilane, triethoxypropylsilane, diethoxyisopropylsilane, triethoxyisopropylsilane, butyldiethoxysilane, butyltriethoxysilane, isobutyldiethoxysilane, isobutyltriethoxysilane, sec-butyldiethoxysilane, sec-butyltriethoxysilane, tert-butyldiethoxysilane, tert-butyltriethoxysilane, 1-methylbutyldiethoxysilane, 1-methylbutyltriethoxysilane, 2-methylbutyldiethoxysilane, 2-methylbutyltriethoxysilane, 3-methylbutyldiethoxysilane, 3-methylbutyltriethoxysilane, 1,1-dimethylpropyldiethoxysilane, 1,1-dimethylpropyltriethoxysilane, 1,2-dimethylpropyldiethoxysilane, 1,2-dimethylpropyltriethoxysilane, 2,2-dimethylpropyldiethoxysilane, 2,2-dimethylpropyltriethoxysilane, triethoxycyclopentylsilane,

dimethoxymethylsilane, dimethoxydimethylsilane, diethoxydimethylsilane, diethyldimethoxylsilane, diethoxydiethylsilane, diethyldipropoxysilane, diisopropyldimethoxysilane, diisopropyldiethoxysilane, di-sec-butyldimethoxysilane, di-sec-butyldiethoxysilane, di-tert-butyldimethoxysilane, or di-tert-butyldiethoxysilane is preferred,

dimethoxymethylsilane, trimethoxymethylsilane, ethyltrimethoxysilane, trimethoxypropylsilane, isopropyltrimethoxysilane, butyltrimethoxysilane, isobutyltrimethoxysilane, sec-butyltrimethoxysilane, tert-butyldimethoxysilane, tert-butyltrimethoxysilane, 1-methyl butyltrimethoxysilane, 1,1-dimethylpropyltrimethoxysilane, 1,2-dimethylpropyltrimethoxysilane,

diethoxymethylsilane, triethoxymethylsilane, ethyltriethoxysilane, triethoxypropylsilane, triethoxyisopropylsilane, butyltriethoxysilane, isobutyltriethoxysilane, sec-butyltriethoxysilane, tert-butyldiethoxysilane, tert-butyltriethoxysilane, 1-methyl butyltriethoxysilane, 1,1-dimethylpropyltriethoxysilane, 1,2-dimethylpropyltriethoxysilane, dimethoxymethylsilane, dimethoxydimethylsilane, diethoxydimethylsilane, diethyldimethoxysilane, or diethoxydiethylsilane.

How to obtain the organosilane compound as the material for the gas barrier film represented by the formula (1) will be described.

The organosilane compounds represented by the formula (1) may be used as they are commercially available, or they may be used as suitably purified or they may be ones suitably synthesized. These organosilane compounds can be synthesized by the method in which an alcohol and/or a metal alkoxide is reacted to an alkyl halosilane compound (Synthesis method 1, the method disclosed e.g. by K. Lin, R. J. Wiles, C. B. Kelly, G. H. M. Davies, G. A. Molander, in ACS Catalysis, 2017, vol. 7, pp. 5129-5133) or the method in which an alkylalkylmagnesium halide or alkyl lithium is reacted to an alkoxysilane (Synthesis method 2, the method disclosed e.g. by S. Masaoka, T. Banno, and M. Ishikawa, in Journal of Organometallic Chemistry, 2006, vol. 691, pp. 182-192). The synthesized organosilane compounds may also be purified by common methods such as recrystallization, distillation, and column chromatography, and used for film deposition.

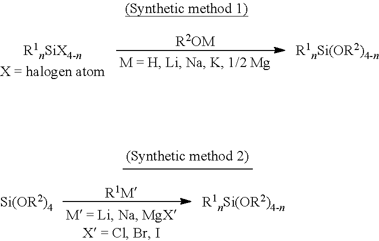

(In the formulas, R¹, R² and n represent the same as R¹, R² and n in the formula (1).)

<Method for Producing Silicon Oxide Film>

The silicon oxide film of the present invention is produced by film-depositing the above material for the gas barrier film by a plasma enhanced chemical vapor deposition method under a condition of a deposition pressure (gauge pressure, the same applies unless otherwise specified) of at least 0.01 Pa and less than 20 Pa.

Here, in the method for producing the silicon oxide film, since the silicon oxide film is produced on a substrate as described below, a laminated film can be produced at the same time.

At the time of producing a silicon oxide film, the film deposition is conducted by a plasma enhanced chemical vapor deposition method (PECVD method), and at that time, it is essential to supply oxygen in addition to the organosilane compound (1). Specifically, at the time of producing a gas barrier film by using an organosilane compound (1) and oxygen as raw materials in the PECVD method, the organosilane compound (1) is vaporized and supplied to the deposition chamber in which the substrate for film deposition is installed. The method for vaporization may, for example, be a method in which the organosilane compound (1) is placed in a heated thermostatic bath and is vaporized by reducing the pressure by using a vacuum pump or the like, or a method in which the organosilane compound (1) is placed in a heated thermostatic bath and is vaporized by blowing-in a carrier gas such as helium, neon, argon, krypton, xenon or nitrogen, or a method in which the organosilane compound (1) is supplied as it is or as a solution to a vaporizer, and it is heated and vaporized in the vaporizer (liquid injection method).

As the solvent to be used to make the solution, 1,2-dimethoxyethane, diglyme, triglyme, dioxane, tetrahydrofuran, an ether such as cyclopentyl methyl ether, a hydrocarbon such as hexane, cyclohexane, methylcyclohexane, ethylcyclohexane, heptane, octane, nonane, decane, benzene, toluene, ethylbenzene, xylene, etc. may be exemplified. One of these may be used alone, or two or more of them may be used as mixed in an optional ratio.

The organosilane compound (1) and oxygen supplied to the deposition chamber will be reacted by the plasma generated in the chamber to form a gas barrier film on the substrate for film-deposition. The film deposition may be carried out by plasma alone, but, light irradiation or heating of the substrate for film-deposition may be used in combination.

The source of the plasma is not particularly limited, and capacitively coupled plasma, inductively coupled plasma, helicon wave plasma, surface wave plasma, electron cyclotron resonance plasma, etc. may be mentioned.

As the deposition equipment to be used for the production of the silicon oxide film, a chemical vapor deposition equipment to be normally used by those skilled in the art, may be employed, and, for example, a batch system, a single-wafer system, or a roll-to-roll system, may be mentioned.

The pressure in the deposition chamber is required to be in the range of at least 0.01 Pa and less than 20 Pa, and is preferably at least 0.1 Pa and less than 15 Pa from such a viewpoint that the WVTR of the obtainable gas barrier film will be low, and controlling the vacuum level will be easy.

The power of the radio frequency power supply (RF power supply) is preferably at least 100 W, and is more preferably from 200 W to 1,500 W from such a viewpoint that the WVTR of the obtainable gas barrier film will be low.

The density of the power to be applied to the electrodes for the plasma discharge is preferably at least 0.1 W/cm², and is more preferably from 2.0 W/cm² to 100 W/cm² from such a viewpoint that the WVTR of the obtainable gas barrier film will be low.

The temperature of the substrate during film-deposition is not particularly limited and is at most the heat-resistant temperature of the substrate, and is preferably in the range of from 0° C. to 300° C.

There is no particular limit to the type of the substrate for film deposition, and for example, polyethylene terephthalate (PET), polyethylene naphthalate (PEN), polycarbonate (PC), polyamide (PA), polyimide (PI), cycloolefin polymer (COP), polyethylene (PE), polypropylene (PP), polystyrene (PS), polyvinyl chloride (PVC), polyvinyl alcohol (PVA), triacetyl cellulose (TAC), polyethersulfone (PES), cycloolefin copolymer (COC), polyacrylonitrile (PAN), ethylene-vinyl alcohol copolymer (EVOH), ABS resin, methacrylate resin, epoxy resin, modified polyphenylene ether, polyacetal, polybutylene terephthalate, polyacrylate, polyarylate, polysulfone, polyamideimide, polyetherimide, polyphenylene sulfide, polyether ether ketone, fluororesin, etc., may be mentioned.

When the flow rate of the organosilane compound (1) supplied during film-deposition is X, and the flow rate of oxygen supplied is Y, the ratio (Y/X) of the oxygen to the organosilane compound (1) is preferably at least 1, more preferably from 5 to 100.

### EXAMPLES

Hereinafter, the present invention will be described in more detail with reference to Examples, but the present invention is not thereby limited.

A gas barrier film was formed on a substrate by using a common CVD apparatus to carry out film-deposition by a capacitively coupled PECVD method. As the substrate for film-deposition, a polyethylene naphthalate (PEN) film having a thickness of 125 μm (visible light transmittance: 88.3%, surface roughness: Ra 0.71 nm) and a polyethylene terephthalate (PET) film having a thickness of 125 μm (visible light transmittance: 89.3%, surface roughness: Ra 1.17 nm) were used. As raw material gases, an organosilane compound vaporized in a thermostatic bath, oxygen gas and argon gas were used. Further, as the power source, a high-frequency power supply with a frequency of 13.56 MHz was used.

The film thickness of the deposited film was estimated by taking a cross-sectional image of the film by using a field emission scanning electron microscope (manufactured by JEOL, FE-SEM) JSM-7600F.

The water vapor transmission rate (WVTR) to be an index for gas barrier performance, was measured by a gas chromatography method (GC method) by using a moisture transmission rate measuring device (GTR 3000 series, manufactured by GTR Tech).

The film composition (including the carbon concentration) of the gas barrier film was analyzed by using an X-ray photoelectron spectrometer (XPS, manufactured by ULVAC Phi) PHI5000 VersaProbell.

For the analysis of the synthesized organosilane compound (1), the measurements of ¹H-NMR (proton nuclear magnetic resonance spectrum), ¹³C-NMR (carbon-13 nuclear magnetic resonance spectrum) and ²⁹5 i-NMR (silicon 29 nuclear magnetic resonance spectrum) were conducted by using DPX-400 nuclear magnetic resonance spectrometer of Bruker-Avance and using heavy chloroform as the solvent. The measurements of IR (infrared absorption) spectra were conducted by using FT-720 spectrophotometer of Horiba, Ltd. and using DuraSamplIRII (reflectance type) of SensIRtechnologies. The mass spectral measurements were carried out by a gas chromatography mass spectrometer (manufactured by Shimadzu Corporation, GCMS-QP2010 Model), and, as the capillary column, DB-5MS of Agilent Technologies Inc. was used.

### (Example 1) Film Deposition Using Tert-Butyltriethoxysilane

Using tert-butyltriethoxysilane synthesized with reference to the method described by K. Lin, R. J. Wiles, C. B. Kelly, G. H. M. Davies, and G. A. Molander, in ACS Catalysis, 2017, vol. 7, pp. 5129-5133, together with oxygen, a silicon oxide film was deposited on a PEN film by a PECVD method. By setting the supply flow rate of tert-butyltriethoxysilane to be 80 sccm, the oxygen supply flow rate to be 2,100 sccm, the deposition chamber pressure to be 8 Pa, and the power of the radio frequency power supply (RF power supply) with a power supply frequency of 13.56 MHz to be 1,000 W, the film deposition was conducted for 14 minutes. Further, the ratio (Y/X) of the oxygen supply flow rate to the tert-butyltriethoxysilane supply flow rate was 26.3.

The thickness of the obtained silicon oxide film was 800 nm. The composition of the film was Si=33 atom % and 0=67 atom %, and the carbon concentration was less than 1.0 atm %. WVTR was 2.0×10⁻⁴ g/m²·day.

The visible light transmittance of the laminated film consisting of the silicon oxide film and the PEN film was 88.2%. The surface roughness (Ra) was 0.68 nm.

Using tert-butyltriethoxysilane, together with oxygen, a silicon oxide film was deposited on a PEN film by a PECVD method. By setting the supply flow rate of the tert-butyltriethoxysilane to be 80 sccm, the oxygen supply flow rate to be 2,100 sccm, the deposition chamber pressure to be 8 Pa, and the power of the radio frequency power supply (RF power supply) with a power supply frequency of 13.56 MHz to be 1,000 W, the film deposition was conducted for 7 minutes. Further, the ratio (Y/X) of the oxygen supply flow rate to the tert-butyltriethoxysilane supply flow rate was 26.3.

The thickness of the obtained silicon oxide film was 400 nm. WVTR was 4.3×10⁻⁴ g/m²·day. The visible light transmittance of the laminated film consisting of the silicon oxide film and the PEN film was 88.5%.

When tert-butyltriethoxysilane is used and deposited by the PECVD method together with oxygen, even if the silicon oxide film thickness is as thin as 400 nm, WVTR is 10⁻⁴ g/m²·day order i.e. at most 10⁻³ g/m²·day order, and thus, it is suitable as a gas barrier film.

### (Example 2) Film Deposition Using Tert-Butyltriethoxysilane

Using tert-butyltriethoxysilane obtained in the same manner as in Example 1, together with oxygen, a silicon oxide film was deposited on a PET film by a PECVD method. By setting the supply flow rate of tert-butyltriethoxysilane to be of 80 sccm, the oxygen supply flow rate to be 2,100 sccm, the deposition chamber pressure to be 8 Pa, and the power of the radio frequency power supply (RF power supply) with a power supply frequency of 13.56 MHz to be 1,000 W, the film deposition was conducted for 8 minutes. The ratio (Y/X) of the oxygen supply flow rate to the tert-butyltriethoxysilane supply flow rate was 26.3.

The thickness of the obtained silicon oxide film was 500 nm. WVTR was 3.9×10⁻³ g/m²·day. The visible light transmittance of the laminated film consisting of the silicon oxide film and the PET film was 91.0%.

When tert-butyltriethoxysilane is used and deposited by the PECVD together with oxygen, even if the silicon oxide film thickness is as thin as 500 nm, WVTR is in the order of 10⁻³ g/m²·day, and thus it is suitable as a gas barrier film.

### (Example 3) Film Deposition Using Isopropyltrimethoxysilane

Using isopropyltrimethoxysilane synthesized with reference to the method described by K. Lin, R. J. Wiles, C. B. Kelly, G. H. M. Davies, and G. A. Molander, in ACS Catalysis, 2017, vol. 7, pp. 5129-5133, together with oxygen, a silicon oxide film was deposited on a PEN film by a PECVD method. By setting the supply flow rate of isopropyltrimethoxysilane to be 80 sccm, the oxygen supply flow rate to be 2,100 sccm, the deposition chamber pressure to be 8 Pa, and the power of the radio frequency power supply (RF power supply) with a power frequency of 13.56 MHz, to be 1,000 W, the film deposition was conducted for 11 minutes. Further, the ratio (Y/X) of the oxygen supply flow rate to the isopropyltrimethoxysilane supply flow rate was 26.3.

The thickness of the obtained silicon oxide film was 800 nm. The composition of the film was Si=33 atom % and 0=67 atom %, and the carbon concentration was less than 1.0 atm %. WVTR was 2.0×10⁻⁴ g/m²·day.

The visible light transmittance of the laminated film consisting of the silicon oxide film and the PEN film was 88.2%. The surface roughness (Ra) was 0.67 nm.

Using isopropyltrimethoxysilane, together with oxygen, a silicon oxide film was deposited on a PEN film by a PECVD method. By setting the supply flow rate of isopropyltrimethoxysilane to be 80 sccm, the oxygen supply flow rate to be 2,100 sccm, the deposition chamber pressure to be 8 Pa, and the power of a radio frequency power supply (RF power supply) with a power frequency of 13.56 MHz, to be 1,000 W, the film deposition was conducted for 3 minutes. Further the ratio (Y/X) of the oxygen supply flow rate to the isopropyltrimethoxysilane supply flow rate was 26.3.

The thickness of the obtained silicon oxide film was 200 nm. WVTR was 6.9×10⁻⁴ g/m²·day. The visible light transmittance of the laminated film consisting of the silicon oxide film and the PEN film was 88.4%.

When isopropyltrimethoxysilane is used and deposited together with oxygen by the PECVD method, even if the thickness of the silicon oxide film is as thin as 200 nm, WVTR is 10⁻⁴ g/m²·day order, i.e. less than 10⁻³ g/m²·day order, and thus, it is suitable as a gas barrier film.

### (Synthesis Example 1) Synthesis of (1,2-dimethylpropyl)trimethoxysilane

A 500 mL three-necked flask equipped with a magnetic stirrer, a Dimroth condenser, a dropping funnel and a three-way stopcock, was flushed with argon, and 136 g (4.26 mol) of dehydrated methanol, 422 g (4.17 mol) of triethylamine and 1,800 mL of diethyl ether were introduced. While cooling the reaction vessel in an ice bath, from the dropping funnel, 275 g (1.34 mol) of trichloro-1,2-dimethylpropylsilane synthesized in accordance with the method described in the literature (M. G. Voronkov, N. G. Romanova, L. G. Smirnova, Chemicke Listy pro Vedu a Prumysl, vol. 52, pp. 640-653, 1958) was added dropwise over 3.5 hours, and the mixture was stirred at room temperature for further 16 hours. The reaction mixture was filtered through a Buchner funnel to remove solid impurities. The filtrate was concentrated by a rotary evaporator, and hexane was added, followed by washing three times with water. The organic layer was dried over anhydrous magnesium sulphate, then filtered and concentrated again by a rotary evaporator. The obtained mixture was distilled under reduced pressure (boiling point 79° C./3.3 kPa) to obtain 226 g (yield 87.7%) of (1,2-dimethylpropyl)trimethoxysilane as a colorless transparent liquid.

Mass spectrum (El,70 eV) m/z (%) 177 ([M-CH₃]+, 1.1), 121 (Si(OMe)₃+, 100), ¹H-NMR (400 MHz, CDCl₃) δ (ppm) 0.83-0.90 (m, 1H), 0.92-1.00 (m, 9H), 1.78-1.90 (m, 1H), 3.58 (s, 9H), 13C-NMR (100 MHz, CDCl₃) δ (ppm) 10.01, 20.57, 22.09, 23.53, 28.76, 50.65, ²⁹Si— NMR (80 MHz, CDCl₃) 6 (ppm)−43.7, IR (thin film, cm⁻¹) 2956, 2945, 2875, 2841, 1466, 1387, 1375, 1365, 1230, 1190, 1082, 910, 793, 727.

### (Example 4) Film Deposition Using (1,2-Dimethylpropyl) Trimethoxysilane

Using (1,2-dimethylpropyl)trimethoxysilane obtained in Synthesis Example 1, together with oxygen, a silicon oxide film was deposited on a PEN film by a PECVD method. By setting the supply flow rate of (1,2-dimethylpropyl)trimethoxysilane to be 80 sccm, the oxygen supply flow rate to be 2,100 sccm, the pressure of the deposition chamber to be 8 Pa, and the power of the radio frequency power supply (RF power supply) with a power supply frequency of 13.56 MHz to be 1,000 W, the film deposition was conducted for 11 minutes. Further, the ratio (Y/X) of the oxygen flow rate to the (1,2-dimethylpropyl)trimethoxysilane flow rate was 26.3.

The thickness of the obtained silicon oxide film was 800 nm. The composition of the film was Si=33 atom % and 0=67 atom %, and the carbon concentration was less than 1.0 atm %. WVTR was 2.0×10⁻⁴ g/m²·day.

The visible light transmittance of the laminated film consisting of the silicon oxide film and the PEN film was 88.1%. The surface roughness (Ra) was 0.62 nm.

Using (1,2-dimethylpropyl)trimethoxysilane obtained in Synthesis Example 1, together with oxygen, a silicon oxide film was deposited on a PEN film by a PECVD method. By setting the supply flow rate of (1,2-dimethylpropyl)trimethoxysilane to be 80 sccm, the oxygen supply flow rate to be 2,100 sccm, the pressure of the deposition chamber to be 8 Pa, and the power of the radio frequency power supply (RF power supply) to be 1,000 W, the film deposition was conducted for 3 minutes. Further, the ratio (Y/X) of the oxygen flow rate to the (1,2-dimethylpropyl)trimethoxysilane flow rate was 26.3.

The thickness of the obtained silicon oxide film was 250 nm. WVTR was 7.2×10⁻⁴ g/m²·day. The visible light transmittance of the laminated film consisting of the silicon oxide film and the PEN film was 88.2%.

When (1,2-dimethylpropyl)trimethoxysilane is used and deposited together with oxygen by the PECVD method, even if the silicon oxide film thickness is as thin as 250 nm, WVTR is 10⁻⁴ g/m²·day order, i.e. less than 10⁻³ g/m²·day order, and thus it is suitable as a gas barrier film.

### (Example 5) Film Deposition Using Tert-Butyltrimethoxysilane

Using tert-butyltrimethoxysilane synthesized with reference to the method described by K. Lin, R. J. Wiles, C. B. Kelly, G. H. M. Davies, and G. A. Molander, in ACS Catalysis, 2017, vol. 7, pp. 5129-5133, together with oxygen, a silicon oxide films was deposited on a PEN film by a PECVD method. By setting the supply flow rate of tert-butyltrimethoxysilane to be 80 sccm, the oxygen supply flow rate to be 2,100 sccm, the pressure of the deposition chamber to be 8 Pa, and the power of the radio frequency power supply (RF power supply) with a power supply frequency of 13.56 MHz, to be 1,000 W, the film deposition was conducted for 14 minutes. Further, the ratio (Y/X) of the oxygen supply flow rate to the tert-butyltrimethoxysilane supply flow rate was 26.3.

The thickness of the obtained silicon oxide film was 800 nm. WVTR was 4.1×10⁻⁴ g/m²·day. The composition of the film was Si=35 atom % and 0=65 atom %, and the carbon concentration was less than 1.0 atm %.

The visible light transmittance of the laminated film consisting of the silicon oxide film and the PEN film was 88.1%. The surface roughness (Ra) was 0.70 nm.

Using tert-butyltrimethoxysilane, together with oxygen, a silicon oxide film was deposited on a PEN film by a PECVD method. By setting the supply flow rate of tert-butyltrimethoxysilane to be 80 sccm, the oxygen supply flow rate to be 2,100 sccm, the pressure of the deposition chamber to be 8 Pa, and the power of the radio frequency power supply (RF power supply) with a power supply frequency of 13.56 MHz, to be 1,000 W, the film deposition was conducted for 4 minutes. Further, the ratio (Y/X) of the oxygen supply flow rate to the tert-butyltrimethoxysilane supply flow rate was 26.3.

The thickness of the obtained silicon oxide film was 250 nm. WVTR was 8.5×10⁻⁴ g/m²·day. The visible light transmittance of the laminated film consisting of the silicon oxide film and the PEN film was 88.2%.

When tert-butyltrimethoxysilane is used and deposited together with oxygen by the PECVD method, even if the silicon oxide film thickness is as thin as 250 nm, WVTR is 10⁻⁴ g/m²·day order i.e. lower than 10⁻³ g/m²·day order, and thus, it is suitable as a gas barrier film.

### (Example 6) Film Deposition Using Dimethoxydimethylsilane

Using dimethoxydimethylsilane, together with oxygen, a silicon oxide film was deposited on a PEN film by a PECVD method. By setting the supply flow rate of dimethoxydimethylsilane to be 80 sccm, the oxygen supply flow rate to be 2,100 sccm, the pressure of the deposition chamber to be 8 Pa, and the power of the radio frequency power supply (RF power supply) with a power frequency of 13.56 MHz, to be 1,000 W, the film deposition was conducted for 8 minutes. Further, the ratio (Y/X) of the oxygen supply flow rate to the dimethoxydimethylsilane supply flow rate was 26.3.

The thickness of the obtained silicon oxide was 800 nm. WVTR was 7.3×10⁻⁴ g/m²·day. The composition of the film was Si=36 atom % and 0=64 atom %, and the carbon concentration was less than 1.0 atm %.

The visible light transmittance of the laminated film consisting of the silicon oxide film and the PEN film was 88.5%. The surface roughness (Ra) was 0.70 nm.

Using dimethoxydimethylsilane, together with oxygen, a silicon oxide film was deposited on a PEN film by a PECVD method. By setting the supply flow rate of dimethoxydimethylsilane to be 80 sccm, the oxygen supply flow rate to be 2,100 sccm, the pressure of the deposition chamber to be 8 Pa, and the power of the radio frequency power supply (RF power supply) with a power frequency of 13.56 MHz, to be 1,000 W, the film deposition was conducted for 2 minutes. Further, the ratio (Y/X) of the oxygen supply flow rate to the dimethoxydimethylsilane supply flow rate was 26.3.

The thickness of the obtained silicon oxide film was 200 nm. WVTR was 2.0×10⁻³ g/m²·day. The visible light transmittance of the laminated film consisting of the silicon oxide film and the PEN film was 88.3%.

When dimethoxydimethylsilane is used and deposited together with oxygen by the PECVD method, even if the silicon oxide film thickness is as thin as 200 nm, WVTR is in the order of 10⁻³ g/m²·day, and thus, it is suitable as a gas barrier film.

### (Comparative Example 1) Film Deposition Using Hexamethyldisiloxane

Using hexamethyldisiloxane, together with oxygen, a film was deposited on a PEN film by a PECVD method. By setting the supply flow rate of hexamethyldisiloxane to be 80 sccm, the oxygen supply flow rate to be 2,100 sccm, the pressure of the deposition chamber to be 6 Pa, and the power of the radio frequency power supply (RF power supply) with a power frequency of 13.56 MHz, to be 1,000 W, the film deposition was conducted for 7 minutes. Further, the ratio (Y/X) of the oxygen supply flow rate to the hexamethyldisiloxane supply flow rate was 26.3. The thickness of the obtained film was 800 nm. WVTR was 2.8×10⁻³ g/m²·day, thus showing a high value.

Using hexamethyldisiloxane, together with oxygen, a film was deposited on a PEN film by a PECVD method. By setting the supply flow rate of hexamethyldisiloxane to be 80 sccm, the oxygen supply flow rate to be 2,100 sccm, the pressure of the deposition chamber to be 6 Pa, and the power of the radio frequency power supply (RF power supply) with a power frequency of 13.56 MHz, to be 1,000 W, the film deposition was conducted for 2 minutes. Further, the ratio (Y/X) of the oxygen supply flow rate to the hexamethyldisiloxane supply flow rate was 26.3.

The thickness of the obtained film was 200 nm. WVTR was 2.4×10⁻² g/m²·day, thus showing a high value.

The silicon oxide film to be produced by using an organosilane compound represented by the formula (1) of the present invention is suitable as a gas barrier film because it has high gas barrier performance with a WVTR of the order of at most 10⁻³ g/m²·day even at a thickness of at most 500 nm.

In the case of a silane compound outside the range of the organosilane compound represented by the formula (1) of the present invention, as shown by the Comparative Example, when a film is formed, WVTR is higher than the order of 10⁻³ g/m²·day at a film thickness of at most 500 nm, such being unsuitable for a gas barrier film.

1-13. (canceled)

14. A silicon oxide film characterized by satisfying the following requirements (1) and (2):
(1) the water vapor transmission rate (WVTR) at a film thickness of at most 500 nm is at most 9.0×10⁻³ g/m²·day,
(2) the carbon concentration in the film, as measured by X-ray photoelectron spectroscopy (XPS), is at most 3.0 atom %.

15. The silicon oxide film according to claim 14, wherein the water vapor transmission rate (WVTR) at a film thickness of at most 500 nm is from 1.0×10⁻⁶ to 9.0×10⁻³ g/m²·day.

16. A material for a gas barrier film for a chemical vapor deposition method, consisting of an organosilane compound represented by the following formula (1):
Rₙ¹—Si—(OR²)₄₋ₙ (1)
(R¹ represents a C₁₋₂₀ alkyl group or a hydrogen atom, n represents an integer from 1 to 3, when n is at least 2, the plurality of R¹ may be the same or different from one another, or two R¹ may be bonded to each other to form an alkanediyl group, R² represents a C₁₋₁₀ alkyl group, when n is at most 2, the plurality of R² may be the same or different from one another.)

17. The material for a gas barrier film according to claim 16, where R¹ is a hydrogen atom or a C₁₋₅ alkyl group.

18. The material for a gas barrier film according to claim 16, wherein R² is a C₁₋₃ alkyl group.

19. The material for a gas barrier film according to claim 16, wherein R¹ is selected from the group consisting of a hydrogen atom, a methyl group, an ethyl group, a propyl group, an isopropyl group, a butyl group, an isobutyl group, a sec-butyl group, a tert-butyl group, a pentyl group, a cyclopentyl group, a 1-methylbutyl group, a 2-methylbutyl group, a 3-methylbutyl group, a 1-ethylpropyl group, a 1,1-dimethylpropyl group, a 1,2-dimethylpropyl group and a 2,2-dimethylpropyl group.

20. The material for a gas barrier film according to claim 16, wherein the material for a gas barrier film is any one of dimethoxymethylsilane, trimethoxymethylsilane, ethyldimethoxysilane, ethyltrimethoxysilane, dimethoxypropylsilane, trimethoxypropylsilane, dimethoxyisopropylsilane, trimethoxyisopropylsilane, butyldimethoxysilane, butyltrimethoxysilane, isobutyldimethoxysilane, isobutyltrimethoxysilane, sec-butyldimethoxysilane, sec-butyltrimethoxysilane, tert-butyldimethoxysilane, tert-butyltrimethoxysilane, dimethoxypentylsilane, trimethoxypentylsilane, 1-methylbutyldimethoxysilane, 1-methylbutyltrimethoxysilane, 2-methylbutyldimethoxysilane, 2-methylbutyltrimethoxysilane, 3-methylbutyldimethoxysilane, 3-methylbutyltrimethoxysilane, 1,1-dimethylpropyldimethoxysilane, 1,1-dimethylpropyltrimethoxysilane, 1,2-dimethylpropyldimethoxysilane, 1,2-dimethylpropyltrimethoxysilane, 2,2-dimethylpropyldimethoxysilane, 2,2-dimethylpropyltrimethoxysilane, cyclopentyldimethoxysilane, cyclopentyltrimethoxysilane, diethoxymethylsilane, triethoxymethylsilane, diethoxyethylsilane, triethoxyethylsilane, diethoxypropylsilane, triethoxypropylsilane, diethoxyisopropylsilane, triethoxyisopropylsilane, butyldiethoxysilane, butyltriethoxysilane, isobutyldiethoxysilane, isobutyltriethoxysilane, sec-butyldiethoxysilane, sec-butyltriethoxysilane, tert-butyldiethoxysilane, tert-butyltriethoxysilane, diethoxypentylsilane, triethoxypentylsilane, diethoxy-1-methylbutylsilane, triethoxy-1-methylbutylsilane, diethoxy-2-methylbutylsilane, triethoxy-2-methylbutylsilane, diethoxy-3-methylbutylsilane, triethoxy-3-methylbutylsilane, diethoxy-1,1-dimethylpropylsilane, triethoxy-1,1-dimethylpropylsilane, diethoxy-1,2-dimethylpropylsilane, triethoxy-1,2-dimethylpropylsilane, diethoxy-2,2-dimethylpropylsilane, triethoxy-2,2-dimethylpropylsilane, cyclopentyldiethoxysilane, cyclopentyltriethoxysilane, dimethoxydimethylsilane, diethoxydimethylsilane, diethyldimethoxysilane, diethoxydiethylsilane and methoxytrimethylsilane.

21. A method for producing a silicon oxide film as defined in claim 14, wherein a material for a gas barrier film for a chemical vapor deposition method, consisting of an organosilane compound represented by the following formula (1):
Rₙ¹—S—(OR²)₄₋ₙ (1)
(R¹ represents a C₁₋₂₀ alkyl group or a hydrogen atom, n represents an integer from 1 to 3, when n is at least 2, the plurality of R¹ may be the same or different from one another, or two R¹ may be bonded to each other to form an alkanediyl group, R² represents a C₁₋₁₀ alkyl group, when n is at most 2, the plurality of R² may be the same or different from one another), is formed into a film by a plasma enhanced chemical vapor deposition method under such a condition that the deposition pressure is at least 0.01 Pa and less than 20 Pa.

22. The method for producing a silicon oxide film according to claim 21, wherein the film is formed by the plasma enhanced chemical vapor deposition method under such a condition that the power of the radio frequency power supply (RF power supply) is at least 100 W.

23. The method for producing a silicon oxide film according to claim 21, wherein the film is formed by the plasma enhanced chemical vapor deposition method under such a condition that the power density of the radio frequency power supply (RF power supply) is at least 0.1 W/cm².

24. A laminated film comprising a silicon oxide film as defined in claim 14 and a substrate.

25. A gas barrier film made of a silicon oxide film as defined in claim 14.

26. A gas barrier film made of a laminated film as defined in claim 24.
